(19) United States
(12) Patent Application Publication
(10) Pub. No.: US 2023/0300988 A1
(43) Pub. Date: Sep. 21, 2023

(54) METHOD FOR PRODUCING AN ELASTOMERIC COMPONENT COMPRISING A PRINTED STRUCTURE

(71) Applicant: Dätwyler Schweiz AG, Schattdorf (CH)

(72) Inventors: Ronny VRIJENS, Vliermaalroot (BE); Matthias SODDEMANN, Schattdorf (CH); Daniel Joel GLOOR, Steinhausen (CH)

(73) Assignee: Dätwyler Schweiz AG, Schattdorf (CH)

(21) Appl. No.: 18/014,831

(22) PCT Filed: Jun. 30, 2021
(86) PCT No.: PCT/CH2021/050013

§ 371 Date: Jan. 6, 2023

(30) Foreign Application Priority Data
Jul. 7, 2020 (CH) 00836/20

(51) Int. Cl. H05K 3/00; H05K 1/02; H05K 1/03; H05K 3/12

(52) U.S. Cl. CPC H05K 3/0064; H05K 1/0277; H05K 1/0393; H05K 3/12; H05K 2201/0133; H05K 2201/0129

(57) ABSTRACT

A method for producing an elastomeric component, preferably an elastomeric sealing component, including an elastomer body and a printed structure, preferably a printed electronic structure or circuit, on a surface of the elastomer body. The method includes: a. providing a planar foil of thermoplastic material having a printable surface; b. printing a structure onto the printable surface to obtain the printed structure; c. providing an elastomer substrate for forming the elastomer body; d. placing the planar foil with the printed structure onto the elastomer substrate; and e. laminating the combined planar foil and elastomer substrate by applying heat and pressure. The elastomeric component is obtained in that the elastomer substrate is formed to the shape of the elastomer body before step d); the elastomer substrate is formed to the shape of the elastomer body during lamination; or the elastomer substrate is formed to the shape of the elastomer body after lamination.

### TECHNICAL FIELD

The invention is directed to a method for producing an elastomeric component, preferably an elastomeric sealing component, comprising an elastomer body and a printed structure, preferably a printed electronic structure or circuit. The invention further relates to an elastomeric component obtained by said method.

### BACKGROUND

Printing technologies for electronic structures and architectures on different substrates are known. However, if the structures should be printed on a rubber-like substrate with elastomeric properties such as thermoset elastomers, many problems arise, because vulcanized rubber exhibits non-uniform or non-homogenous surface properties. In addition, surface roughness and poor wettability of rubber substrates antagonize good printing results.

DE102008006390 describes a method for gluing flexible circuit boards consisting of layers of copper (electrical conductor) and polyimide (electrical insulator) to a reinforcement plate for complete stiffening or stiffening of desired regions of the circuit board. The method uses heat activated films based on a mixture of reactive resins forming a high-strength three-dimensional polymer network and on elastomers having long lasting elastic properties. The reinforcement plate may be of polymer material, such as polyester, polyethylene terephthalate, polyimides, polyethylene naphthalate or liquid crystal polymers.

The prior art however does not provide a method for efficient manufacturing of an elastomeric component, preferably sealing components, with a printed structure on its surface.

It is hardly possible to directly print fine structures on rubber substrates that do not have a perfectly planar surface, and even more, if the electronic structure should be printed on three-dimensional surfaces. The printing would be very difficult and slow.

Accordingly, there is a need for a workable and cost-efficient method to apply electronic structures to elastomeric substrates.

### SUMMARY OF THE INVENTION

It is an objective of the invention to provide a workable and cost-efficient method for producing elastomeric sealing components, with printed structures, e.g. electronic structures or circuits.

At least one of the objectives of the present invention is achieved by a method according to claim 1. The method for producing an elastomeric component, preferably an elastomeric sealing component, comprising an elastomer body and a printed structure, preferably a printed electronic structure or circuit, on a surface of the elastomer body, comprises the steps of: a.) providing a planar foil of thermoplastic material having a printable surface, b.) printing a structure onto the printable surface of the planar foil to obtain the printed structure, c.) providing an elastomer substrate for forming the elastomer body (4) of the elastomeric sealing component; d.) placing the planar foil with the printed structure on the elastomer substrate, and e.) laminating the combined planar foil and elastomer substrate by applying heat and pressure; wherein the elastomeric component is obtained in that: (i) the elastomer substrate of step c) is formed to the shape of the elastomer body (4) of the elastomeric component before step d); or (ii) the elastomer substrate of step c) is formed to the shape of the elastomer body (4) of the elastomeric component during the lamination step e); or (iii) the elastomer substrate of step c) is formed to the shape of the elastomer body (4) of the elastomeric component after the lamination step e).

In the context of the present invention the elastomeric component is a technical component of a device or an object having elastic properties. In other words, its main function is based on the elasticity of the component at least in certain relevant regions of the component and the printed structure or the foil carrying the printed structure does not impair the function of the elastomeric component.

In a further embodiment, the foil may have elastomeric or elastic properties as well, and the printed structure is at least stretchable without forming cracks when stretched. The elastic properties of the foil may be in the same range as the elastomeric or elastic properties of the elastomer body. Alternatively, the foil including the printed structures may be arranged in regions of the elastomeric component, where the elastomeric properties of the elastomeric component are not used for its proper functioning. In this case, the foil may be flexible without having elastomeric properties and the printed structures do not need to be stretchable.

An elastomeric sealing component is understood as technical component of a device or an object that provides a seal of the device or object. In other words, the sealing component forms a seal against a fluid. Such sealing components are known in the art and a non-limiting list of examples is: a sealing gasket, a sealing membrane, a dosing membrane, a closure, a stopper or a plug (e.g. of a vial), an elongated sealing profile, a seal for a plunger (e.g. of a syringe). The elastomer body is understood as the part of the elastomeric sealing component, which defines the overall shape of the sealing component and is made of an elastomer substrate providing elastomeric properties to the elastomeric sealing component. The elastomer body forms the actual sealing component as listed above.

With the above method it becomes possible to apply printed structures, e.g. electronic structures or circuits, to rubber substrates which often have non-printable surfaces. In addition, the printed structure may be applied even to 3-dimensional surfaces of the rubber substrate, allowing for more versatile shapes and forms of the desired elastomeric sealing component. Another advantage is, that no additional adhesion layer or heat-activatable foil is required for gluing, due to the direct bonding between foil and substrate. Through the 2-step process, one is capable of printing on a planar, 2-D substrate and then in a second step place the printed structure on a 3-D-shaped elastomer object before lamination. Thereby, a variety of applications can be served with additional electronic functionalities. Alternatively, the foil with the printed structure may be placed on a planar surface of a preform of the elastomer object and formed into an object with a 3-D surface during the lamination step or after the lamination step.

The foil with the printed structure may be cut to leave a small rim surrounding the printed area of the foil having a width sufficient for proper bonding to the elastomer substrate. Such a rim may be especially useful when the printed structure is facing the surface of the substrate.

The printed structure may be printed with conductive and/or non-conductive (e.g. dielectric) ink to obtain printed electronic structures or circuits. The structures may be printed using known printing technologies such as screen printing, flexographic printing, gravure printing, relief printing, inkjet printing, piezo-inkjet printing, aerosol jet printing, stencil printing, offset printing, doctor blade printing, rotary screen printing, intaglio printing, digital printing, capillary printing, electrohydrodynamic printing, tampography, microcontact printing, laser printing.

The structures may be further connected to electronic components placed and attached to the planar foil. The structures may be e.g. a sensor or an antenna.

The planar foil may have a thickness in the range of 10 to 1000 micrometres, preferably to 75 micrometres.

A particularly efficient method is to provide a foil with a plurality of printed structures for individual elastomeric sealing components. The foil with the plurality of printed structures may be placed on the elastomer substrate in the form of a sheet. After or during lamination of the foil and the elastomer sheet individual elastomeric sealing components are produced by forming the elastomer body from the elastomer substrate and cutting out the individual elastomeric sealing components.

Further embodiments of the invention are set forth herein.

In some embodiments, the heat and pressure treatment during the laminating step d) may create chemical bonding, in particular covalent bonds, between the foil and the body. At the same time, the planar foil may be adapted to the 3-dimensional surface of the elastomer substrate of the elastomer body. The temperature used for laminating may be in the range of 120° C. to 160° C. Processing times of less than 60 seconds can be achieved for the lamination.

In some embodiments, the surface of the elastomer substrate of the elastomer body may be modified to achieve better bonding between the foil and the elastomer body before the laminating step e). Therefore, the surface may be subjected to plasma or corona treatment, without the use of additional bonding agents. Such surface treatment increases the bonding ability between foil and elastomer substrate of the elastomer body. Alternatively, a bonding agent only may be applied.

In some embodiments, the printed structure may be cured and/or dried after the printing step b) and before step d) is performed.

In some embodiments, after the printing step b) the printed structure is protected with a second foil of the same material as the planar foil or coated with a dielectric layer of dielectric ink or lacquer.

In some embodiments, the planar foil may be placed on the elastomer substrate of the elastomer body such that the printed structure faces the elastomer body. Alternatively, the planar foil may be placed on the elastomer substrate of the elastomer body such that the printed structure faces away from the elastomer body.

In some embodiments, the elastomer substrate of the elastomer body is made of a thermoset elastomer or a thermoplastic elastomer. The elastomeric material can be, for example, a synthetic or natural rubber, such as butyl rubber, isoprene rubber, butadiene rubber, halogenated butyl rubber (e.g., bromobutyl rubber), ethylene propylene terpolymer, silicone rubber, fluoro- or perfluoroelastomers, chlorosulfonate, polybutadiene, butyl, neoprene, nitrile, polyisoprene, buna-N, copolymer rubbers such as ethylene-propylene (EPR), ethylene-propylene-diene monomer (EPDM), acrylonitrile-butadiene (NBR or HNBR) and styrene-butadiene (SBR), blends such as ethylene or propylene-EPDM, EPR, or NBR, combinations thereof. The term “synthetic rubbers” also should be understood to encompass materials which alternatively may be classified broadly as thermoplastic or thermosetting elastomers such as polyurethanes, silicones, fluorosilicones, styrene-isoprene-styrene (SIS), and styrene-butadiene-styrene (SBS), as well as other polymers which exhibit rubber-like properties such as plasticized nylons, polyolefins, polyesters, ethylene vinyl acetates, fluoropolymers, and polyvinyl chloride.

In some embodiments, the planar foil may be made of a material selected from thermoplastic polyurethane (TPU), liquid silicone rubber (LSR), fluoropolymer (e.g. tetrafluoroethylene resin (PTFE), tetrafluoroethylen-perfluoroethylene copolymer (PFA), tetrafluoroethylene-hexafluoroethylene copolymer (FEP), tetrafluoroethylene-ethylene copolymer (ATFE), polytrichlorotrifluoroethylene (PCTFE), polyfluorinated vinylidene (PVDF), polyfluorinated vinyl (PVF)), ultra-high-molecular-weight polyethylene (UHMW-PE), or an expanded fluoropolymer based foil. E.g. a TPU foil may adapt to the mechanical properties of the elastomer body, such as flexibility, stretchability and elasticity. The material of the printed structure may be accordingly chosen from stretchable materials, such as stretchable inks or pastes.

In some embodiments, the planar foil may be further provided with electronic components connected to the printed structure, before it is placed on the elastomer body.

In some embodiments, the surface of the elastomer substrate of the elastomer body for applying the electronic structure or circuit may be non-planar before the laminating step e) or is formed into a non-planar surface during the laminating step e).

The invention further relates to an elastomeric sealing component, preferably manufactured by the above method, comprising an elastomer body formed from an elastomer substrate and a thermoplastic foil laminated to a surface of the elastomer substrate for forming the elastomer body, the thermoplastic foil comprising a printed structure, preferably a printed electronic structure or circuit, on a printable surface of the foil.

In some embodiments, the elastomer substrate for forming the elastomer body may be made of a thermoset elastomer or a thermoplastic elastomer. The material may be selected from the materials described above.

In some embodiments, the thermoplastic foil may be made of a material selected from thermoplastic polyurethane, liquid silicone rubber (LSR), fluoropolymer (e.g. tetrafluoroethylene resin (PTFE), tetrafluoroethylen-perfluoroethylene copolymer (PFA), tetrafluoroethylene-hexafluoroethylene copolymer (FEP), tetrafluoroethylene-ethylene copolymer (ATFE), polytrichlorotrifluoroethylene (PCTFE), polyfluorinated vinylidene (PVDF), polyfluorinated vinyl (PVF)), ultra-high-molecular-weight polyethylene (UHMW-PE), or an expanded fluoropolymer based foil.

In some embodiments, the printed structure may be arranged on a non-planar surface of the elastomer body.

The described method is not only applicable to the production of elastomeric sealing components but also to other elastomeric products or elastomeric components such as elastomeric sensor pads or elastomeric soft and dry electrodes for medical devices, or to elastomeric tubes for conducting fluids, or to elastomeric housings or casings, e.g. of mobile phones; or to elastomeric touch buttons, touch pads or keyboards. These products and components can be seen as different individual inventions.

### BRIEF DESCRIPTION OF THE DRAWINGS

The invention is described in greater detail below with reference to embodiments that are illustrated in the figures. The figures show:

FIG. 1A an elastomeric component with a printed structure;

FIG. 1B an exploded view of the elastomeric component of FIG. 1A; and

FIGS. 2A-2D under FIGS. 2A to 2D steps of a method for manufacturing the elastomeric component of FIGS. 1A and 1B.

### EMBODIMENTS OF THE INVENTION

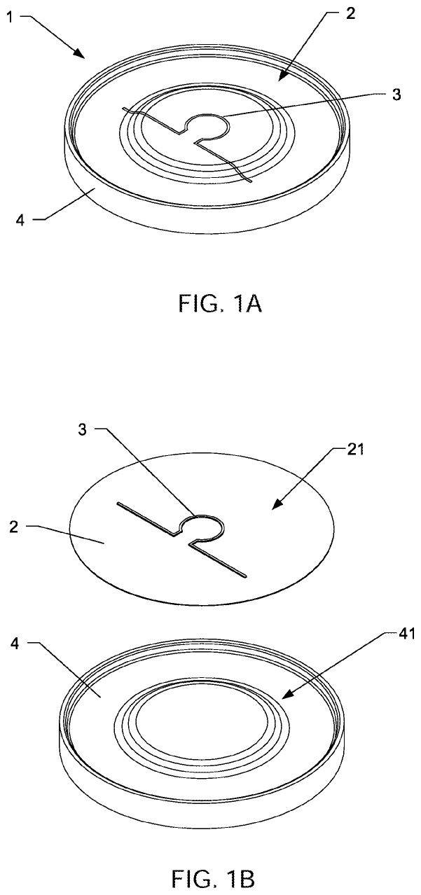

FIG. 1A shows an example of an elastomeric sealing component 1, in the form of a sealing membrane, comprising an elastomer body 4, which in the shown example has a non-planar surface 41. The elastomeric component 1 further comprises a printed structure 3 on the non-planar surface 41 of the elastomer body 4. The printed structure 2 may be an electronic structure or circuit, e.g. a sensor structure or an antenna as shown in FIGS. 1A and 1B. The elastomeric component 1 further comprises a thermoplastic foil 2, which in a laminated state is covering and is adapted to the non-planar surface 41 of the elastomer body 4. FIG. 1B shows an exploded view of the elastomeric component of FIG. 1A with the thermoplastic foil 2 in its planar state before lamination, as described in more detail below.

Printing directly onto an elastomer body encounters problems due the anisotropy of the elastomer material and the resulting non-uniform on non-homogenous surface properties. The printing becomes even more difficult and prone to failures if the surface onto which the structure should be printed is not planar.

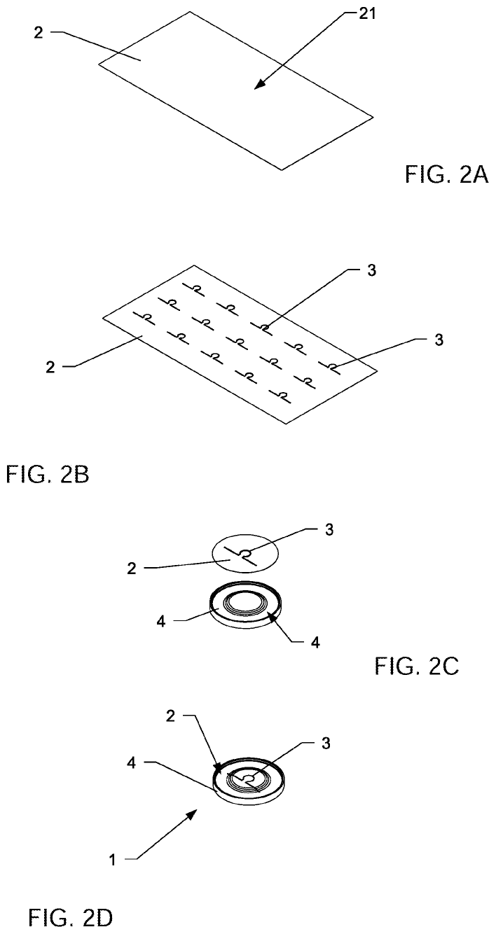

FIGS. 2A-2D show different steps of a method for manufacturing the elastomeric component 1 of FIGS. 1A and 1B. In a first step (FIG. 2A), a planar foil 2 with a printable surface 21 is provided. Good results have been achieved with a thermoplastic polyurethane (TPU) foil with a thickness of 25 to 75 micrometres.

In a second step (FIG. 2B), a structure is printed onto the printable surface with standard printing technologies using a stretchable material, e.g. a stretchable silver ink, to obtain the printed structure 3.

In a third step (FIG. 2C), the planar foil 2 with the printed structure 3 is cut to the desired size and placed on a surface of the elastomer body 4. In the shown example on the non-planar surface 41 of the elastomer body 4. The foil 2 can be arranged in a way that the printed structure 3 faces the elastomer body 4 or that it faces away from the elastomer body 4. In both cases the printed structure 3 may be protected with a coating or another planar foil of e.g. TPU.

In a fourth step (FIG. 2D), the combined planar foil 2 including the printed structure 3 and the elastomer body 4 are laminated by applying heat and pressure to obtain the elastomeric component 1. During lamination, the foil 2 and the printed structure 3 are adapted to the non-planar surface 41 of the elastomer body 4. The lamination further leads to chemical bonding between the thermoplastic foil 3 and the elastomer body. Increased bonding may be achieved by activating the surface of the elastomer body, e.g. by plasma treatment.

Alternatively, the entire foil 2 may be laminated to a sheet of elastomer substrate (not shown). The elastomer body may then be formed either during or after the lamination step. Individual elastomeric components may be obtained after cutting.

### REFERENCE SIGNS

1 elastomeric component
2 planar foil
21 printable surface
3 printed structure
4 elastomer body
41 non-planar surface

1.-16. (canceled)

17. A method for producing an elastomeric component comprising an elastomer body and a printed structure on a surface of the elastomer body, the method comprising:
a. providing a planar foil of thermoplastic material having a printable surface;
b. printing a structure onto the printable surface (21) of the planar foil (2) to obtain the printed structure (3);
c. providing an elastomer substrate for forming the elastomer body of the elastomeric sealing component;
d. placing the planar foil with the printed structure onto the elastomer substrate; and
e. laminating the combined planar foil (2) and elastomer substrate by applying heat and pressure,
wherein the elastomeric component is obtained in that
the elastomer substrate of step c is formed to the shape of the elastomer body of the elastomeric component before step d; or
the elastomer substrate of step c is formed to the shape of the elastomer body of the elastomeric component during the lamination step e; or
the elastomer substrate of step c is formed to the shape of the elastomer body of the elastomeric component after the lamination step e.

18. The method according to claim 17, wherein the foil has elastic properties and the printed structure is at least stretchable without forming cracks when stretched.

19. The method according to claim 17, wherein during the laminating step e the heat and pressure treatment creates chemical bonding between the planar foil and the elastomer substrate of the elastomer body.

20. The method according to claim 17, wherein the temperature used for laminating is 120° C. to 160° C.

21. The method according to claim 17, wherein the surface of the elastomer substrate for forming the elastomer body is modified for achieving a better bonding between the foil and the elastomer substrate for forming the elastomer body before the laminating step e.

22. The method according to claim 17, wherein after the printing step b the printed structure is cured and/or dried before step d is performed.

23. The method according to claim 17, wherein after the printing step b) the printed structure is protected with a second foil of the same material as the planar foil or coated with a dielectric layer of dielectric ink or lacquer.

24. The method according to claim 17, wherein the planar foil is placed on the elastomer substrate for forming the elastomer body such that the printed structure faces the elastomer body or wherein the planar foil is placed on the elastomer substrate for forming the elastomer body such that the printed structure faces away from the elastomer body.

25. The method according to claim 17, wherein the elastomer substrate for forming the elastomer body is made of a thermoset elastomer or a thermoplastic elastomer.

26. The method according to claim 17, wherein the planar foil is made of a material selected from thermoplastic polyurethane, liquid silicone rubber, fluoropolymer, ultra-high-molecular-weight polyethylene, and expanded fluoropolymers.

27. The method according to claim 17, wherein the planar foil is further provided with electronic components connected to the printed structure.

28. The method according to claim 17, wherein the surface of the elastomer substrate for forming the elastomer body for applying the electronic structure or circuit is non-planar before the laminating step e or is formed into a non-planar surface during the laminating step e.

29. The method according to claim 17, wherein the elastomeric component is an elastomeric sealing component and the printed structure is a printed electronic structure or circuit.

30. The method according to claim 17, wherein the surface of the elastomer substrate for forming the elastomer body is modified with a bonding agent or by plasma or corona treatment to achieve a better bonding between the foil and the elastomer substrate for forming the elastomer body before the laminating step e.

31. An elastomeric sealing component comprising an elastomer body formed from an elastomer substrate and a thermoplastic foil laminated to a surface of the elastomer substrate for forming the elastomer body, the thermoplastic foil comprising a printed structure on a printable surface of the foil.

32. The elastomeric sealing component according to claim 31, wherein the elastomer substrate for forming the elastomer body is made of a thermoset elastomer or a thermoplastic elastomer.

33. The elastomeric sealing component according to claim 31, wherein the thermoplastic foil is made of a material selected from thermoplastic polyurethane (TPU), liquid silicone rubber (LSR), fluoropolymer (e.g. tetrafluoroethylene resin (PTFE), tetrafluoroethylen-perfluoroethylene copolymer (PFA), tetrafluoroethylene-hexafluoroethylene copolymer (FEP), tetrafluoroethylene-ethylene copolymer (ATFE), polytrichlorotrifluoroethylene (PCTFE), polyfluorinated vinylidene (PVDF), polyfluorinated vinyl (PVF)), ultra-high-molecular-weight polyethylene (UHMW-PE), and expanded fluoropolymers.

34. The elastomeric sealing component according to claim 31, wherein the printed structure is arranged on a non-planar surface of the elastomer body.
